(19) United States
(12) Patent Application Publication
(10) Pub. No.: US 2004/0263186 A1
(43) Pub. Date: Dec. 30, 2004

(54) Capacitance type dynamic quantity sensor

(76) Inventors: Mitsuo Yarita, Chiba-shi (JP); Minoru Sudou, Chiba-shi (JP); Kenji Katou, Chiba-shi (JP)

Correspondence Address: ADAMS & WILKS, ATTORNEYS AND COUNSELORS AT LAW, 31st FLOOR, 50 BROADWAY, NEW YORK, NY, 10004, US

(21) Appl. No.: 10/844,291

(22) Filed: May 12, 2004

(30) Foreign Application Priority Data
May 13, 2003 (JP) 2003-134552
Apr. 27, 2004 (JP) 2004-130793

(51) Int. Cl. G01R 27/26; H01G 7/00

(52) U.S. Cl. 324/662

(57) ABSTRACT

The present invention provides a capacitance type dynamic quantity sensor which is miniature and inexpensive. A capacitance detection electrode formed on a lower glass plate is made conductive up to an outer surface of an upper glass plate via through-holes formed so as to vertically and perfectly extend through the upper glass plate, and solder balls. Thus, the electrodes to be connected to an external substrate are collectively provided on the outer surface of the upper glass plate to allow the capacitance type dynamic quantity sensor to be directly mounted to an external substrate.

### BACKGROUND OF THE INVENTION

1. Field of the Invention

The present invention relates to a capacitance type dynamic quantity sensor for detecting angular velocity or acceleration of an automobile or the like.

2. Description of the Related Art

A conventional semiconductor capacitance type acceleration sensor is shown in FIG. 11. A semiconductor capacitance type acceleration sensor 507 includes a silicon plate 502 having a weight 521 which is adapted to be displaced due to acceleration applied thereto, an upper glass plate 503 having an electrode 531 through which displacement of the weight 521 due to the acceleration is adapted to be detected in the form of a capacitance change, and a lower glass plate 501 having an electrode 511 through which the displacement of the weight 521 due to the acceleration is adapted to be detected in the form of the capacitance change. The silicon plate 502, the upper glass plate 503 and the lower glass plate 501 are laminated and accommodated inside a package 504 to allow the semiconductor capacitance type acceleration sensor to be mounted to an external substrate. The electrode 511 formed on an upper surface of the lower glass plate 501 is electrically connected to an electrode wiring pattern 561 formed on a base plate 506 through a through-hole 512. The electrode wiring pattern 561 is connected to arbitrary electrode pins 505 to be connected to an external circuit. The electrode 531 formed on a lower surface of the upper glass plate 503 is electrically connected to electrode pads 533 provided on an upper surface of the upper glass plate 503 through a through-hole 532. Also, the electrode 531 is connected to arbitrary electrode pins 505 through Au wires 551 extending from the respective electrode pads 533 to be electrically connected to an external circuit (refer to JP 9-243654 A (page 6 and FIG. 2) for example).

However, as described above, when a plurality of electrodes are arranged on a plurality of surfaces, respectively, the wires or the like are necessary for electrical connection to a substrate of an external device or the like, and hence promotion of low cost is not realized. In addition, since the package is required to protect the wires, miniaturization and promotion of low cost are not realized. Also, a substrate having the electrode pattern is required for a package stand, which does not lead to promotion of low cost.

### SUMMARY OF THE INVENTION

In the light of the foregoing, it is, therefore, an object of the present invention to provide a capacitance type dynamic quantity sensor which is miniature and inexpensive.

A capacitance type dynamic quantity sensor according to the present invention includes: a silicon substrate having a weight adapted to be displaced due to a dynamic quantity such as acceleration; a first plate for supporting the silicon substrate from a lower surface side having the weight formed thereon; a second plate for supporting the silicon substrate from an upper surface; and a first capacitance detection electrode formed on the first plate for detecting displacement of the weight based on a difference in electrostatic capacity fluctuation. The sensor is characterized by further including: a second capacitance detection electrode formed on the second plate for detecting the displacement of the weight based on the difference in electrostatic capacity fluctuation; a first electrode formed so as to vertically and completely extend through the second plate; a second electrode formed so as to vertically and completely extend through the second plate to be connected to the second capacitance detection electrode; and a solder member through which the first electrode and the first capacitance detection electrode are electrically connected to each other.

Further, the capacitance type dynamic quantity sensor according to the present invention is characterized in that each of the first and second plates is a glass plate.

Further, the capacitance type dynamic quantity sensor according to the present invention is characterized by further including: a first electrode pattern formed on an upper surface of the second plate so as to be connected to the first electrode; and a second electrode pattern formed on the upper surface of the second plate so as to be connected to the second electrode.

As described above, the capacitance type dynamic quantity sensor according to the present invention can be directly mounted to a substrate without requiring a wire bonding process since the electrodes are collectively provided on one surface. Thus, promotion of low cost can be realized. In addition, since an external package becomes unnecessary, miniaturization and promotion of low cost can be realized.

### BRIEF DESCRIPTION OF THE DRAWINGS

In the accompanying drawings:

FIGS. 1A and 1B are a plan view showing a capacitance type acceleration sensor according to Embodiment 1 of the present invention, and a cross sectional view taken along line A-A′ of FIG. 1A;

FIGS. 2A and 2B are a plan view of a lower glass plate of the capacitance type acceleration sensor according to Embodiment 1 of the present invention, and a transmission side elevational view of the capacitance type acceleration sensor according to Embodiment 1 of the present invention;

FIGS. 3A to 3C are a plan view of an upper glass plate of the capacitance type acceleration sensor according to Embodiment 1 of the present invention, a bottom view of the upper glass plate of the capacitance type acceleration sensor according to Embodiment 1 of the present invention, and a cross sectional view taken along line B-B′ of FIG. 3A;

FIGS. 4A and 4B are a plan view of a silicon plate of the capacitance type acceleration sensor according to Embodiment 1 of the present invention, and a cross sectional view taken along line C-C′ of FIG. 4A;

FIGS. 5A to 5C are a schematic cross sectional view before joining the silicon plate and the upper glass plate of the capacitance type acceleration sensor according to Embodiment 1 of the present invention, a schematic cross sectional view after joining the silicon plate and the upper glass plate of the capacitance type acceleration sensor according to Embodiment 1 of the present invention, and a schematic cross sectional view of an electrode through which upper and lower silicon members of a weight of the capacitance type acceleration sensor according to Embodiment 1 of the present invention are electrically connected to each other;

FIG. 6 is a cross sectional view of a capacitance type angular velocity sensor according to Embodiment 2 of the present invention;

FIG. 7 is a plan view of a lower glass plate of the capacitance type angular velocity sensor according to Embodiment 2 of the present invention;

FIG. 8 is a plan view of a silicon plate of the capacitance type angular velocity sensor according to Embodiment 2 of the present invention;

FIGS. 9A and 9B are a plan view of an upper glass plate of the capacitance type angular velocity sensor according to Embodiment 2 of the present invention, and a bottom view of the upper glass plate of the capacitance type angular velocity sensor according to Embodiment 2 of the present invention;

FIGS. 10A and 10B are a conceptual view showing a state of a weight before angular velocity is applied to the capacitance type angular velocity sensor according to Embodiment 2 of the present invention, and a conceptual view showing a motion of the weight when the angular velocity is applied to the capacitance type angular velocity sensor according to Embodiment 2 of the present invention; and

FIG. 11 is a cross sectional view showing a semiconductor capacitance type acceleration sensor of a related art example.

### DESCRIPTION OF THE PREFERRED EMBODIMENTS

A capacitance type dynamic quantity sensor of the present invention includes a silicon plate having a weight adapted to be displaced due to acceleration or the like applied thereto, a lower glass plate as a first plate, and an upper glass plate as a second plate. In addition, a first capacitance detection electrode of the lower glass plate is electrically connected to a first electrode of the upper glass plate through a ball-like solder member. Electrodes are collectively arranged on an outer surface of the upper glass plate so as to allow the capacitance type dynamic quantity sensor to be directly mounted to an external substrate.

As for a basic manufacturing method, first of all, the lower glass plate is prepared, and the silicon plate is then joined to the lower glass plate. After completion of the joining, the ball-like solder member through which the capacitance detection electrode of the lower glass plate is intended to be connected to a part of the electrodes of the upper glass plate are arranged in predetermined positions of the first capacitance detection electrode of the lower glass plate. Thereafter, the upper glass plate is joined to the silicon plate.

A capacitance type acceleration sensor according to Embodiment 1 of the present invention and a capacitance type angular velocity sensor according to Embodiment 2 of the present invention will hereinafter be described in detail with reference to the accompanying drawings.

### Embodiment 1

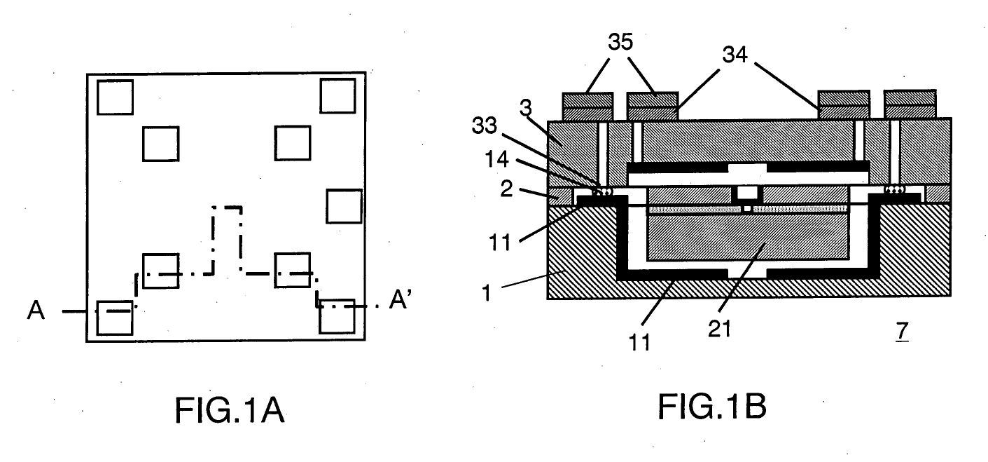

FIG. 1A is a plan view showing a capacitance type acceleration sensor according to Embodiment 1 of the present invention. FIG. 1B is a cross sectional view taken along line A-A′ of FIG. 1A.

A capacitance type acceleration sensor 7 has a structure in which there is laminated a lower glass plate 1 having capacitance detection electrodes 11, a silicon plate 2 having a weight 21 adapted to be displaced due to acceleration applied thereto, and an upper glass plate 3 having a capacitance detection electrode 31 and external electrodes 35. The capacitance type acceleration sensor can to be directly mounted to an external substrate through the external electrodes 35. In addition, solder balls 14 are arranged in parts of the capacitance detecting electrodes 11 on the lower glass plate 1. Each of the solder balls 14 has a height enough for the capacitance detection electrodes 11 to be able to contact electrodes 33 of the upper glass plate 3. Thus, the capacitance detection electrodes 11 of the lower glass plate 1 can be electrically connected to the electrodes 33 of the upper glass plate 3.

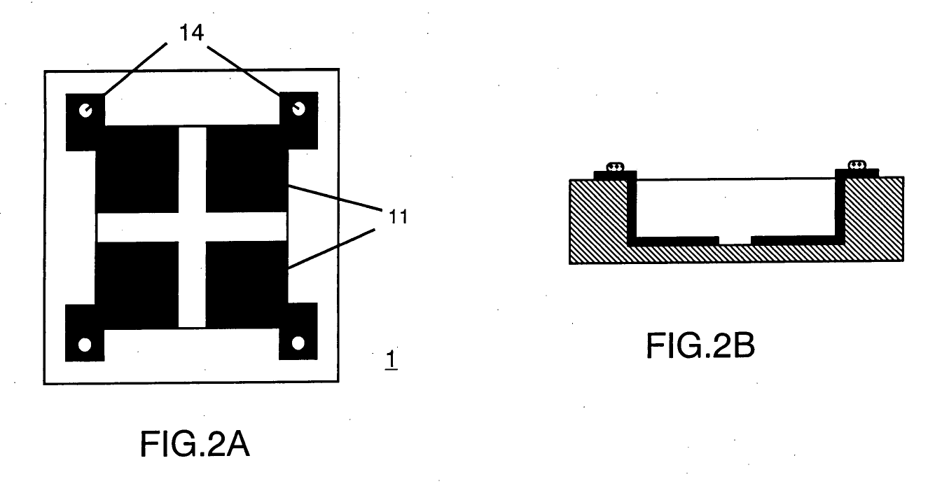

FIG. 2A is a plan view of the lower glass plate of the capacitance type acceleration sensor according to Embodiment 1 of the present invention. FIG. 2B is a transmission side elevational view of the lower glass plate of the capacitance type acceleration sensor according to Embodiment 1 of the present invention.

The lower glass plate 1 is made of SiO₂ as a main constituent. Thus, such a material as to be fitted in thermal expansion coefficient to the silicon plate 2 is used for the lower glass plate 1. In addition, a thickness of the lower glass plate 1 is equal to or larger than about 500 μm. Four electrodes 11 for capacitance detection made of Al or the like having a thickness equal to or smaller than about 1 μm are formed through a sputtering process or the like on a joining surface side of the lower glass plate 1 to the silicon plate 2. These electrodes 11 are connected to the electrodes 33 of the upper glass plate 3 through the solder balls 14, respectively, allowing the electrical joining between the electrodes 11 and the electrode 33 to be carried out.

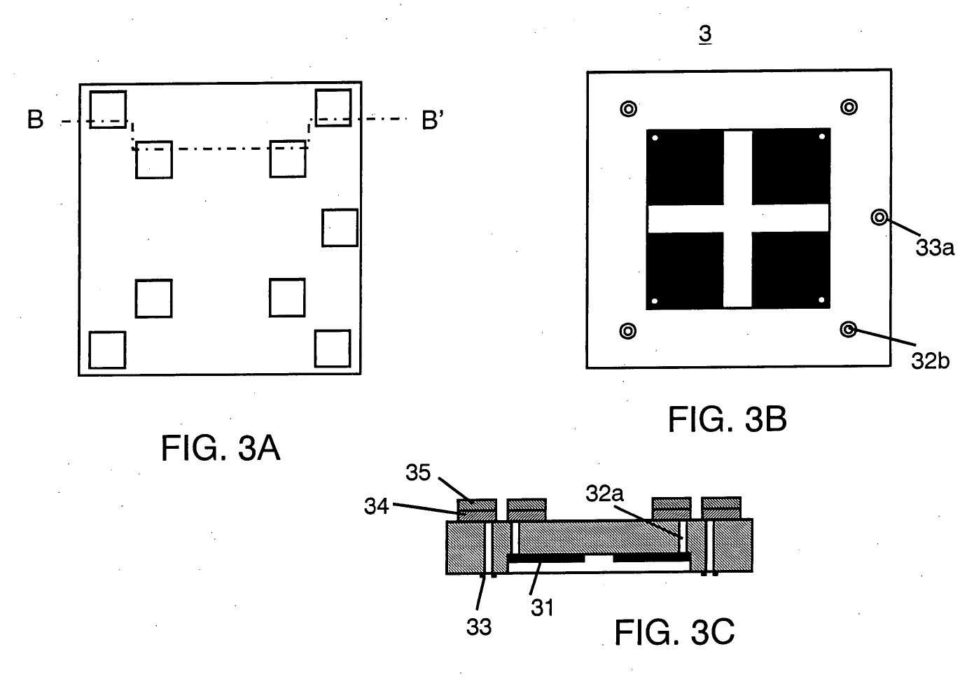

FIG. 3A is a plan view of the upper glass plate of the capacitance type acceleration sensor according to Embodiment 1 of the present invention. FIG. 3B is a bottom view of the upper glass plate of the capacitance type acceleration sensor according to Embodiment 1 of the present invention. FIG. 3C is a cross sectional view taken along line B-B′ of FIG. 3B.

The upper glass plate 3, similarly to the lower glass plate 1, is also made of SiO₂ as a main constituent. Thus, such a material as to be fitted in thermal expansion coefficient to the silicon plate 2 is used for the upper glass plate 3. In addition, a thickness of the upper glass plate 3 is equal to or larger than about 100 μm. The electrodes 31 for capacitance detection made of Al or the like having a thickness equal to or smaller than about 1 μm are arranged in positions on a surface which is sunken with respect to the joining surface of the upper glass plate 3 to the silicon plate 2 by several microns. The electrodes 31 for capacitance detection are electrically connected to N-type silicon members 34 joined to an outer surface of the upper glass plate 3 via through-holes 32a, respectively. The through-holes 32a are filled with Al by sputtering Al similarly to the case of the electrodes 31. In addition, electrodes 33 to be connected to the respective solder balls 14, and an electrode 33a through which an electric potential at the weight 21 of the silicon plate 2 is obtained are formed through the sputtering process on a joining surface of the upper glass plate 3 to the silicon plate 2. The electrodes 33 and 33a are electrically connected to the N-type silicon member 34 joined to the outer surface of the upper glass plate 3 via through-holes 32b, respectively. The through-holes 32b are filled with Al by sputtering Al similarly to the case of the electrodes 33 and 33a. Aluminum is deposited onto the outer surface of the N-type silicon members 34 through the sputtering process in order to form electrode pads 35 made of Al. The electrode pads 35 allow the capacitance type acceleration sensor according to Embodiment 1 of the present invention to be directly mounted to an external substrate.

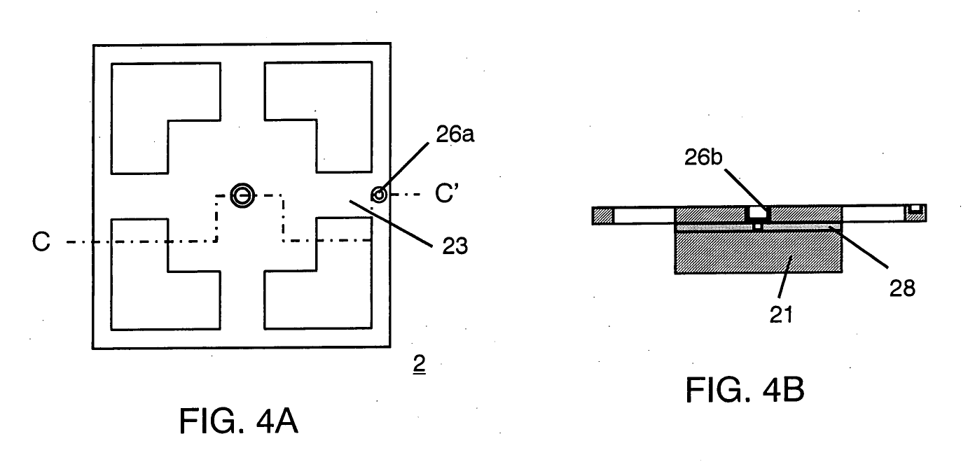

FIG. 4A is a plan view of the silicon plate of the capacitance type acceleration sensor according to Embodiment 1 of the present invention. FIG. 4B is a cross sectional view taken along line C-C′ of FIG. 4A.

For the purpose of making a processing for forming a weight 21 simple, an SOI substrate having an insulating layer 28 formed therein is used as the silicon plate 2. The weight 21 adapted to be displaced due to acceleration applied thereto from the outside is formed at a center portion of the silicon plate 2 through an etching process. An electric potential at the weight 21 is obtained from an electrode 26a in the external terminals 35 through the electrode 33a of the upper glass plate 3. Thus, the weight 21 can be controlled from the outside.

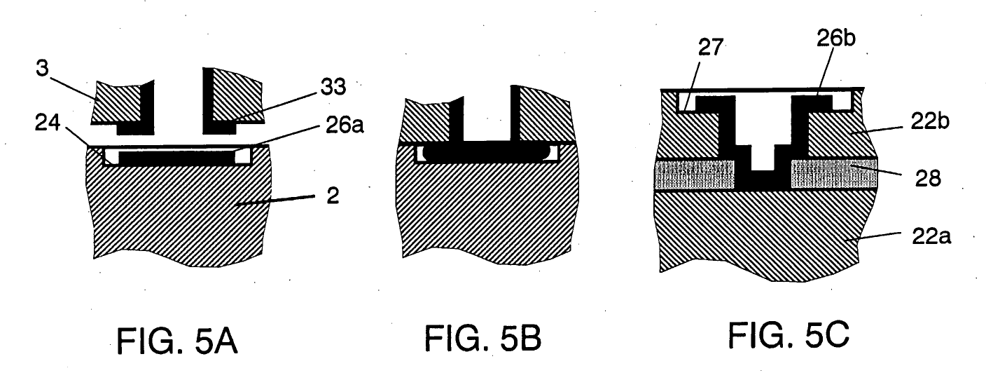

FIGS. 5A and 5B show conceptual cross sectional views explaining a situation in which the Al electrode 33 is pressed against the Al electrode 26a using a pressure to obtain electrical joining. As shown in FIGS. 5A and 5B, in order to obtain the electrical joining, the Al electrodes 33 and 26a are crushed by application of a pressure so as to be accommodated in a recess portion 24 formed in the silicon plate 2.

In addition, FIG. 5C shows a conceptual cross sectional view of an electrode through which electrical conduction is obtained between upper and lower silicon members of the weight 21. In the silicon substrate 2 forming the weight 21, a lower silicon member 22a and an upper silicon member 22b are insulated from each other through an insulating layer 28. Thus, in order to make the upper and lower silicon members 22a and 22b of the weight 21 equal in electric potential to each other, a stepwise recess portion 27 is formed so as to vertically and perfectly extend throughout the upper silicon member 22b and the insulating layer 28 to reach the lower silicon member 22a, and an Al electrode 26b is then formed so as to cover the stepwise recess portion 27 and its bottom portion of the lower silicon member 22a through the sputtering process.

Moreover, the silicon plate 2 has beam portions 23 for supporting the weight 21 and portions for anode joining to the lower and upper glass plates 1 and 3.

As for a basic method including manufacturing the capacitance type acceleration sensor 7, after positions of the lower glass plate 1 and the silicon plate 2 are aligned to an arbitrary position, the lower glass plate 1 and the silicon plate 2 are joined to each other. For the joining, the anode joining is used in which a voltage of about 400 V is applied across the lower glass plate 1 and the silicon plate 2 at an ambient atmosphere temperature of about 300° C.

Next, the solder balls 14 are mounted to the predetermined positions on the lower glass plate 1. Thereafter, positions of the upper glass plate 3 and the silicon plate 2 joined to the lower glass plate 1 are aligned to an arbitrary position to join the upper glass plate 3 and the silicon plate 2 to each other through the anode joining process. In addition, the solder balls 14 are also deformed due to the heat during the anode joining to allow the electrical bonding between the upper and lower electrodes to be obtained.

Above, the structure as described above is adopted for the capacitance type acceleration sensor according to Embodiment 1 of the present invention, and hence the electrodes are collectively provided on one surface. Thus, the capacitance type acceleration sensor can be directly mounted to a substrate without requiring the wire bonding process, and therefore promotion of low cost can be realized. In addition, since an external package becomes unnecessary, miniaturization and promotion of low cist can be realized.

Moreover, while the capacitance type acceleration sensor has been described, the capacitance type acceleration sensor of the present invention is not intended to be limited to the capacitance type acceleration sensor according to Embodiment 1.

### Embodiment 2

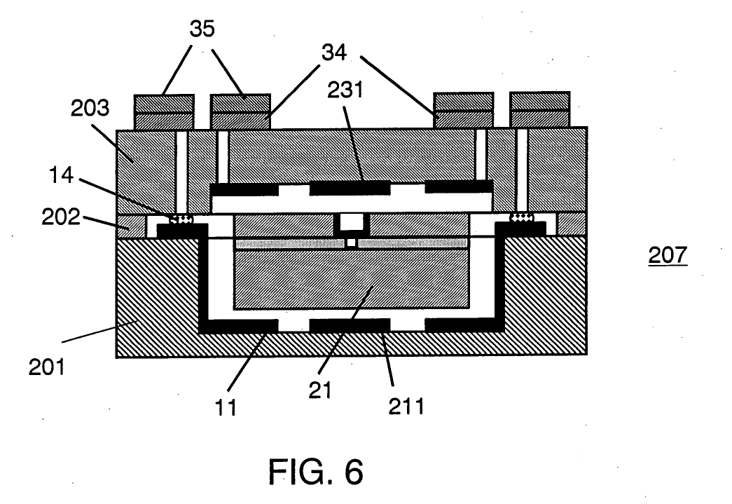

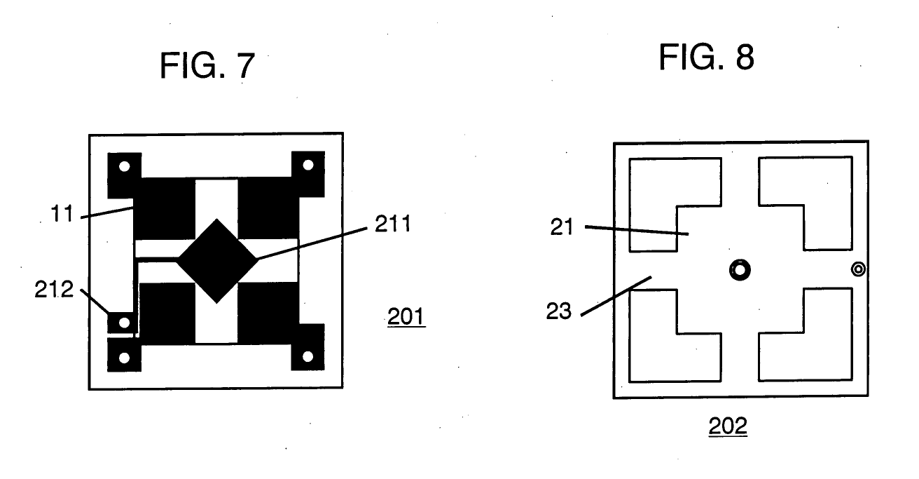

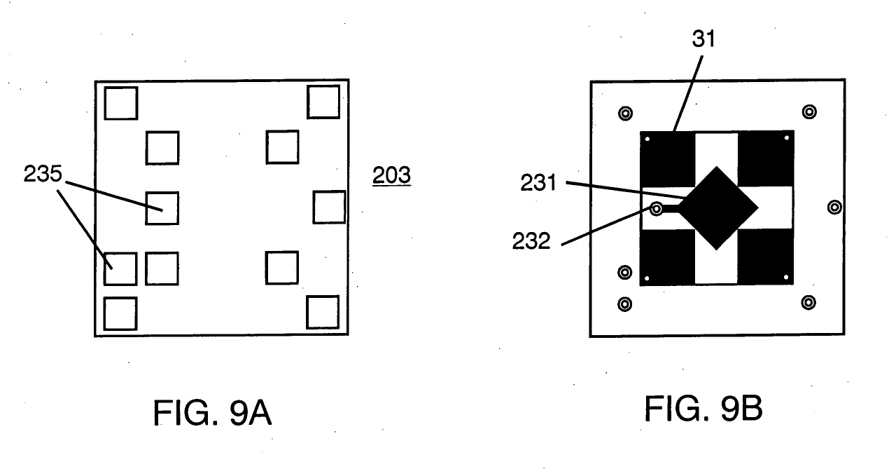

FIG. 6 is a cross sectional view of a capacitance type angular velocity sensor 207 according to Embodiment 2 of the present invention. FIG. 7 is a plan view of a lower glass plate of the capacitance type angular velocity sensor 207 according to Embodiment 2 of the present invention. In FIG. 7, there are shown electrodes arranged on a capacitance detection side of a lower glass plate 201. FIG. 8 is a plan view of a silicon plate of the capacitance type angular velocity sensor 207 according to Embodiment 2 of the present invention. In FIG. 8, a structure is shown having a weight 21 formed at a center of a silicon plate 202 and beams 23 for supporting the weight 21. FIG. 9A is a plan view of an upper glass plate 203 of the capacitance type angular velocity sensor 207 according to Embodiment 2 of the present invention. In FIG. 9A, a structure is shown having electrodes 235 which are arranged on an upper glass plate 203 and through which the capacitance type angular velocity sensor 207 according to Embodiment 2 of the present invention is to be connected to an external substrate. FIG. 9B is a bottom view of the upper glass plate 203 of the capacitance type angular velocity sensor 207 according to Embodiment 2 of the present invention. In FIG. 9B, a structure is shown having an electrode 231 for excitation of the weight 21 and capacitance detection electrodes 31 which are arranged on a capacitance detection side of the upper glass plate 203.

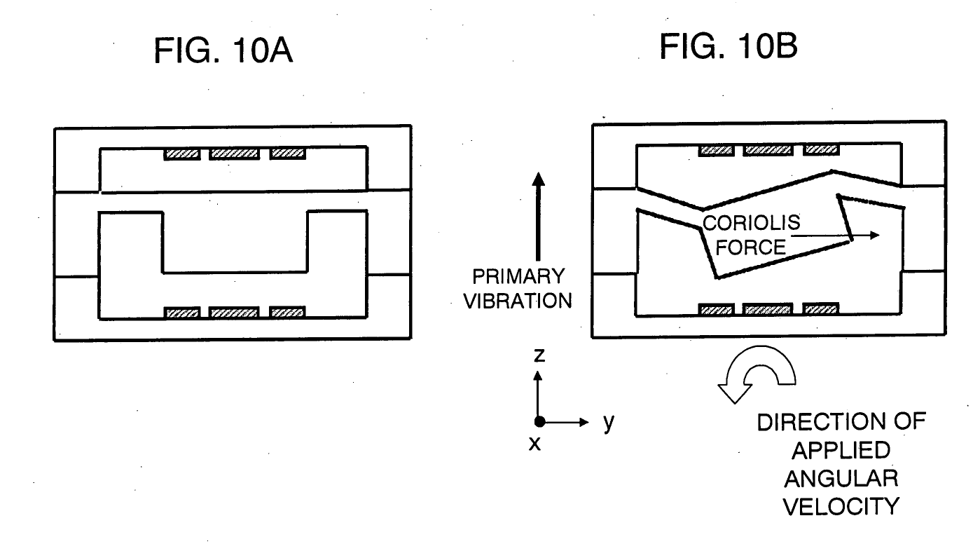

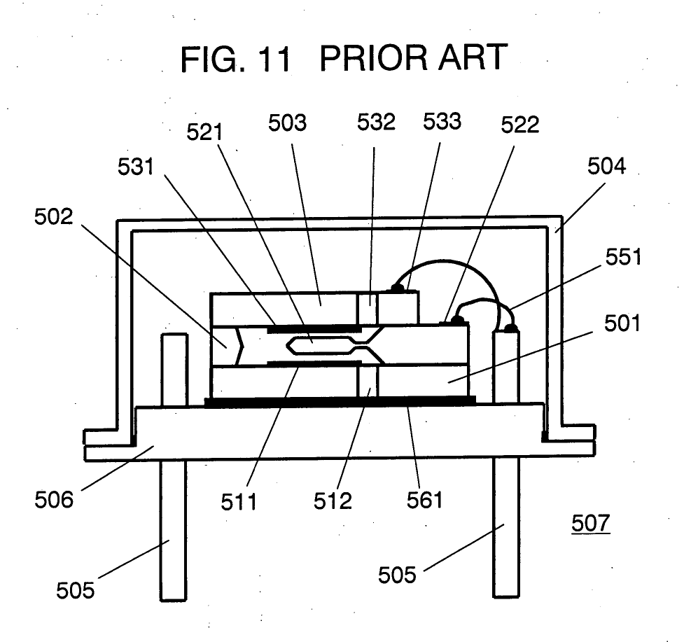

FIGS. 10A and 10B are conceptual views showing a motion of the weight when angular velocity is applied to the capacitance type angular velocity sensor 207 according to Embodiment 2 of the present invention. In FIGS. 10A and 10B, there is conceptually shown a Coriolis force which is generated in the weight when angular velocity is applied from the outside. An electrode 211 arranged at a center of the lower glass plate 201 and an electrode 231 arranged at a center of the upper glass plate 203 are electrodes used to excite the weight 21 formed at a center of the silicon plate 202 in a direction of the Z-axis. When a first sine wave and a second sine wave 180° out of phase with the first sine wave are applied to these electrodes, respectively, the weight 21 vibrates in the Z-axis direction. At this time, if the capacitance type angular velocity sensor 207 suffers angular velocity applied around the X-axis in FIG. 10B from the outside, then the Coriolis force proportional to the vibration in the Z-axis direction is generated in the Y-axis direction in FIG. 10B. The weight 21 is displaced due to the Coriolis force. As a result, an electrostatic capacity obtained between the upper and lower electrodes also fluctuates. This fluctuation value is different from the electrostatic capacity fluctuation due to only a vibration in the Z-axis direction having no applied angular velocity. The capacitance type angular velocity sensor can be realized by detecting this difference in electrostatic capacity fluctuation from the electrodes.

As described above, the structure similar to that of the capacitance type acceleration sensor according to Embodiment 1 of the present invention is adopted for the capacitance type angular velocity sensor as well according to Embodiment 2 of the present invention. Thus, the electrodes are collectively provided on one surface, and hence the capacitance type angular velocity sensor can be directly mounted to a substrate without requiring the wire bonding process. As a result, promotion of low cost can be realized. In addition, since an external package becomes unnecessary, miniaturization and promotion of low cost can be realized.

In addition, while the capacitance type angular velocity sensor has been described, the capacitance type angular velocity sensor of the present invention is not intended to be limited to the capacitance type angular velocity sensor according to Embodiment 2.

What is claimed is:

1. A capacitance type dynamic quantity sensor, comprising:
a silicon substrate having a weight adapted to be displaced due to a dynamic quantity;
a first plate for supporting the silicon substrate from a lower surface side having the weight formed thereon;
a second plate for supporting the silicon substrate from an upper surface;
a first capacitance detection electrode formed on the first plate for detecting displacement of the weight based on a difference in electrostatic capacity fluctuation;
a second capacitance detection electrode formed on the second plate for detecting the displacement of the weight based on the difference in electrostatic capacity fluctuation;
a first electrode formed so as to vertically and completely extend through the second plate;
a second electrode formed so as to vertically and completely extend through the second plate to be connected to the second capacitance detection electrode; and
a solder member through which the first electrode and the first capacitance detection electrode are electrically connected to each other.

2. A capacitance type dynamic quantity sensor according to claim 1, wherein each of the first and second plates is a glass plate.

3. A capacitance type dynamic quantity sensor according to claim 1, further comprising:
a first electrode pattern formed on an upper surface of the second plate so as to be connected to the first electrode; and
a second electrode pattern formed on the upper surface of the second plate so as to be connected to the second electrode.

4. A capacitance type dynamic quantity sensor according to claim 1, wherein the dynamic quantity is acceleration.

5. A capacitance type dynamic quantity sensor according to claim 1, wherein the dynamic quantity is angular velocity.
